(19) United States
(12) Patent Application Publication
(10) Pub. No.: US 2007/0069748 A1
(43) Pub. Date: Mar. 29, 2007

(54) Probe assembly

(76) Inventors: Hidehiro Kiyofuji, Aomori-ken (JP); Yutaka Minato, Aomori-ken (JP); Akihisa Akahira, Aomori-ken (JP)

Correspondence Address: Jeffrey J. King, Esq.;BLACK LOWE & GRAHAM PLLC, Suite 4800, 701 Fifth Avenue, Seattle, WA, 98104, US

(21) Appl. No.: 11/585,416

(22) Filed: Oct. 23, 2006

Related U.S. Application Data
(63) Continuation of application No. PCT/JP05/14873, filed on Aug. 9, 2005.

(51) Int. Cl. G01R 31/02

(52) U.S. Cl. 324/754

(57) ABSTRACT

A probe assembly comprises a probe base plate with a plurality of probes to be used for electrical inspection of a plurality of semiconductor chip regions continuously formed in alignment in the directions orthogonal to each other on a substantially circular semiconductor wafer, and capable of contacting the electrical connecting portions of each semiconductor chip region. The tips of a plurality of probe groups are arranged in the X and Y directions orthogonal to each other on the surface of the probe base plate in correspondence to predetermined chip region groups including the predetermined number of semiconductor chip regions. The arrangement regions of the probe groups are formed discontinuously in both of the X and Y directions. The relative feeding movement of the semiconductor wafer in either of the X and Y directions enables the electrical inspection of all the chip region groups on the semiconductor wafer.

### CROSS REFERENCE TO RELATED APPLICATIONS

This application claims the priority benefit of copending PCT/JP2005/014873, filed Aug. 9, 2005 which is incorporated herein by reference.

### TECHNICAL FIELD

The present invention relates to a probe assembly suitable for use in electrical inspection of an electric circuit such as a plurality of integrated circuits (hereinafter referred to simply as “IC”) formed on a semiconductor wafer.

### BACKGROUND OF THE INVENTION

This conventional type probe assembly has a probe base plate and a plurality of probes extending from the probe base plate, wherein a tester for electrical inspection and each IC is electrically connected by bringing probe tips into contact with an electric connection terminal of each IC chip region formed on a semiconductor wafer. Some testers cannot deal with collective measurement of all the ICs on the semiconductor wafer.

Therefore, depending on the ability of the tester, it has been proposed to partition the plural ICs on the semiconductor wafer into a plurality of linear regions, and to repeat testing every partitioned region on the semiconductor wafer by using a probe assembly in which the linear probe groups corresponding to the regions are arranged on the probe base plate (see, e.g., Patent Document 1: Japanese Patent Application Public Disclosure No. 7-235572 Official Gazette), or to partition the plural ICs on the semiconductor wafer into a plurality of block-like regions and repeat testing every partitioned region on the semiconductor wafer by using a probe assembly with a plurality of probes two-dimensionally arranged in correspondence to the partitioned regions (see, e.g., Patent Document 2: Japanese Patent Appln. Public Disclosure No. 11-121553 Official Gazette). Also, a method of selecting alternately the plural chip regions to be inspected so that the regions to be inspected on the semiconductor wafer may not adjoin (see, e.g., Patent Document 3: Japanese Patent Application Public Disclosure No. 2003-297887 Official Gazette).

Meanwhile, even by using the method of alternately selecting electrically such non-adjoining regions for inspection, such a probe assembly is one with probes arranged continuously and densely corresponding to the vertical and lateral directions irrespectively of the selected regions.

Also, because of recent improvement in ability of testers, it has become possible to perform a so-called collective measurement inspection by using a probe assembly having the number of probes corresponding to all the ICs formed on a single semiconductor wafer. In such a case, however, it is necessary to form on the probe base plate continuously and densely a great number of probes corresponding to the electrical connection terminals for inspection of all the ICs formed on a single semiconductor wafer vertically and laterally in correspondence to the arrangement patterns of the ICs. Therefore, it prevents facile production of the probe assembly.

### SUMMARY OF THE DISCLOSURE OF THE INVENTION

Problems to Be Solved by the Invention

An object of the present invention is to provide a probe assembly which can simultaneously inspect as many ICs as possible and be produced relatively easily.

Another object of the present invention is to provide a probe assembly capable of effectively using each probe, in addition to the above-mentioned object.

Means to Solve the Problems

The probe assembly according to the present invention is used for electrical inspection of a plurality of semiconductor chip regions formed continuously in alignment on a substantially circular semiconductor wafer in the directions orthogonal to each other. It is a probe assembly comprising a probe base plate with a plurality of probes capable of contacting an electric connecting portion of each semiconductor chip region formed, wherein the probe base plate has a size large enough to cover the semiconductor wafer; wherein tips of plural probe groups are arranged in the X and Y directions orthogonal to each other of one face of the probe base plate in correspondence to a predetermined rectangular chip region group including the predetermined number of semiconductor chip regions; wherein the arrangement regions of the tips of the probe group are formed discontinuously in both X and Y directions, and wherein electrical inspection of all the chip region groups on the semiconductor wafer are enabled by feeding movement in either of the X or Y direction relative to the semiconductor wafer.

If the arrangement region of the tips is formed to correspond to all the semiconductor chip regions, that is, to the ICs on the semiconductor wafer, it is necessary to arrange the probes continuously and with a high density on the probe base plate in its X and Y directions in correspondence to all the IC forming regions for inspection. Such a continuous arrangement, therefore, necessitates a technique for sophisticated highly dense arrangement in the X and Y directions of the probes, so that facile production becomes difficult.

On the other hand, according to the present invention, the arrangement regions for the tips of the probe base plate are formed discontinuously in both X and Y directions, so that the arrangement regions of the tips can be scattered within the regions for inspection of the semiconductor wafer equivalent to the above-mentioned continuous arrangement in the X and Y directions, thereby facilitating the probe forming process in comparison with the conventional continuous arrangement. Besides, the relative feeding movement to the semiconductor wafer in either one of the X direction or Y direction enables electrical inspection of all the chip region groups on the semiconductor wafer, so that an easy-to-produce probe assembly is provided without greatly lowering the inspection efficiency in comparison with simultaneous inspection.

Furthermore, it is desirable to arrange probe tips such as follows for performing inspection of one semiconductor wafer at the smallest possible number of measurements and to use a plurality of probes effectively.

In other words, for example, when electrical inspection is repeated accompanying movement in the Y direction, it is desirable to form arrangement regions and non-arrangement regions of the tips of the probe groups, respectively, in the probe base plate regions corresponding to the rectangular chip regions located on the upstream side opposite to the moving direction in each line of the semiconductor wafer along the Y direction, and to form non-arrangement regions and arrangement regions on the probe base plate so that the arrangement region of the tips corresponding to the predetermined number of rectangular chip regions and the non-arrangement regions with no tips arranged may be repeated in each line with the same pattern in the moving direction.

This enables to measure all the measurement regions by the number of times of repetitions corresponding to the number of the non-arrangement regions, so that a probe assembly with a few probes that do not contribute to measurement off the chip region.

For example, it is possible to alternately arrange in each row the arrangement region of the tips corresponding to one rectangular chip region group and the non-arrangement regions corresponding to two rectangular chip region groups in the Y direction. This array enables to inspect all the measurement regions on a single semiconductor wafer by measuring twice in total, displacing by the distance of one rectangular chip region group in the Y direction.

Also, for instance, it is possible to alternately arrange the arrangement region of the tips corresponding to one rectangular chip region group and the non-arrangement regions corresponding to the three rectangular chip region groups in each row in the Y direction. This array enables to inspect all the measurement regions on a single semiconductor wafer by measuring three times in total, displacing by the distance of one rectangular chip region group in the Y direction.

The pattern of the arrangement regions and non-arrangement regions of the tips of the probe groups may be made asymmetric with respect to the center line along the Y direction.

### BRIEF DESCRIPTION OF THE DRAWINGS

FIG. 1 is a bottom view showing an example of arrangement of tips of the probe groups of the probe assembly according to the present invention.

FIG. 2 is a front elevation of the probe assembly according to the present invention.

FIG. 3 is a top view showing a test region of each chip region on a semiconductor wafer to be subjected to an electrical inspection by the probe assembly shown in FIGS. 1 and 2.

FIG. 4 is a view similar to FIG. 3 showing a test region of each chip region on the semiconductor wafer corresponding to the arrangement example of tips of the probe groups of another probe assembly according to the present invention.

FIG. 5 is a view similar to FIG. 3 showing a test region of each chip region on the semiconductor wafer corresponding to an arrangement example of tips of the probe group of yet another probe assembly according to the present invention.

### EXPLANATION OF REFERENCE NUMERALS

10 probe assembly

12 wiring board

14 probe base plate

16 probe

20 semiconductor wafer

α arrangement region

### BEST MODE FOR CARRYING OUT THE INVENTION

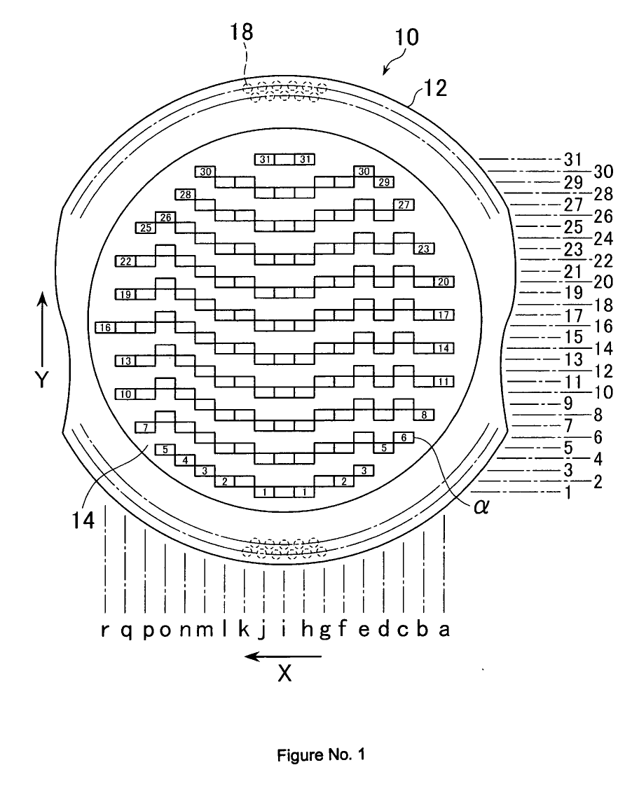

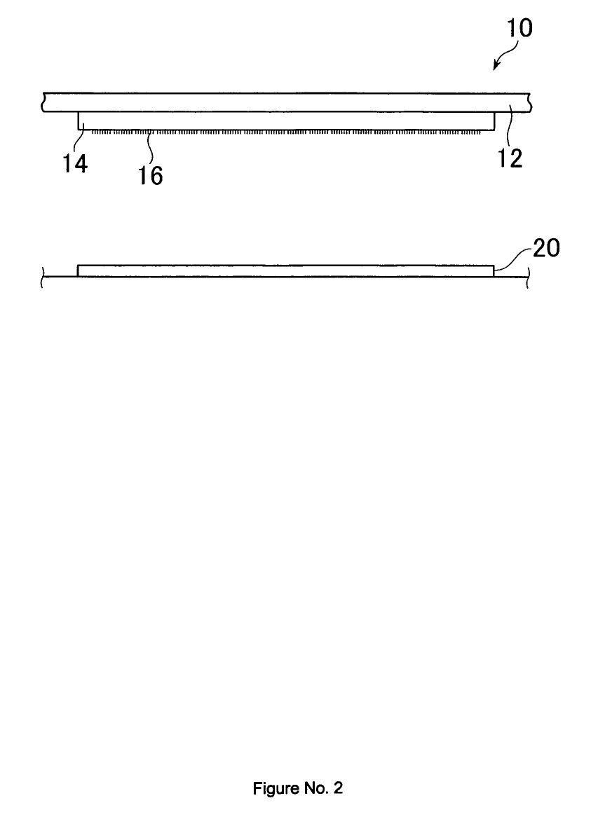

The probe assembly 10 according to the present invention is shown in FIGS. 1 and 2. FIG. 1 is a bottom view with the probe assembly 10 seen from below, and FIG. 2 is a front elevation of the probe assembly.

The probe assembly 10 has, as shown in FIGS. 1 and 2, a generally circular wiring board 12 and a probe base plate 14 attached to the underside of the wiring board, and a plurality of probes 16 (see FIG. 2) are supported on the probe base plate 14.

The wiring board 12 is formed with a wiring circuit (not shown) assembled into an insulated plate made of an electrically insulating material such as epoxy resin reinforced, for example, by glass fibers. On the top face of the wiring board 12, tester lands 18 (see FIG. 1) which are connection terminals to a tester (not shown) are annularly arranged. Also, on the underside of the wiring board 12, connection pads for connecting the corresponding tester lands are formed through the wiring circuit.

The probe base plate 14, as is well known, connects each probe 16 provided on its underside to the respectively corresponding connection pads of the wiring board 12. Each probe 16, therefore, is connected to the tester through the corresponding connection pad and each tester land 18 corresponding to the connection pad.

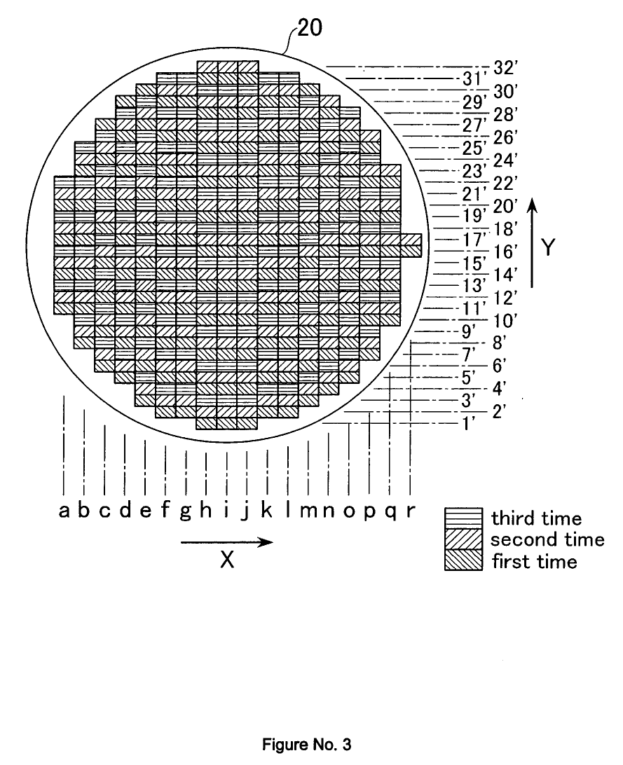

The probe assembly 10 is, as shown in FIG. 2, used for electrical inspection of the plural IC chip regions (see FIG. 3) formed on the semiconductor wafer 20, and the IC chip regions are separated from each other after the inspection to form a plurality of IC chips. For electrical inspection of the plural IC chip regions, each probe 16 is connected with the connection pad of each IC chip region, whereby the tester and the semiconductor wafer 20 to be tested by the tester are connected electrically to each other.

As shown in FIG. 3, the IC chip regions are formed on the semiconductor wafer 20. The IC chip regions are aligned in the X direction and the Y direction orthogonal to each other in FIG. 3 and are uniformly formed continuously within the circular region of the semiconductor wafer 20. For convenience' sake, in FIG. 3, in order to show each IC chip region, rows a to r are shown on the semiconductor wafer 20 along the X direction, and likewise, lines 1′ to 32′ are shown in the Y direction orthogonal to the X direction on the semiconductor wafer 20.

In the illustration, each IC chip region designated in each row and line corresponds to each IC chip, and each IC chip region can be constituted by a plurality of IC chip groups adjacent to each other in the X and Y directions.

Each IC chip region on the semiconductor wafer 20, that is, the probe base plate 14 of the probe assembly 10 to be used for inspection of the IC chips has a diameter substantially equal to the diameter of the semiconductor wafer so as to cover the surface of the semiconductor wafer 20, and the plural probes 16 are provided on the probe base plate 14. In FIG. 1, arrangement regions of the tips of respective groups of probes 16 are aligned in the X and Y directions.

Since the underside of the probe base plate 14 shown in FIG. 1 and the surface of the semiconductor wafer 20 shown in FIG. 3 are arranged so as to oppose each other at the time of inspection in a relation of mirror symmetry with respect to the X directions. The probe assembly 10 is fed and moved in the Y direction with respect to the semiconductor wafer 20 at the time of inspection. Since this movement is a relative movement, it is possible to move the semiconductor wafer 20 in the reverse direction (−Y direction) in place of movement in the Y direction of the probe assembly 10.

The region where the tip of the probe 16 is positioned, that is, the arrangement regions of the tips of the probe 16 groups are shown by rectangular regions α by void in FIG. 1. In FIG. 1, only one region is shown by the symbol α to represent all the arrangement regions of the probe 16 groups as shown by the void rectangular regions, and the symbol α is omitted for other arrangement regions for simplification of the drawings.

As apparent from the comparison between FIGS. 1 and 3, the arrangement regions α of the probe 16 groups are formed to scatter over the whole area of the probe base plate 14 in correspondence to the formation region of each IC region on the semiconductor wafer 20. Further, there are formed a plurality of non-arrangement regions having no probes 16, that is, no tips of the probes 16 arranged in spite of the IC regions on the semiconductor wafer 20, with dispersion on the probe base plate 14. As a result, the arrangement regions α are discontinuously formed in both X and Y directions.

In the example shown in FIG. 1, when the rows h, i and j in the center of the probe base plate 14 are noticed, the arrangement regions α are formed on the first line corresponding to the line 1′ of the rows h, i and j on the semiconductor wafer 20 shown in FIG. 3, i.e., the most upstream side opposite to the moving direction of the probe assembly 10. However, the second and third lines are non-arrangement regions. Thereafter, on the rows h, i and j of the probe base plate 14, the repetition pattern of the arrangement regions α and the non-arrangement regions continues from the fourth line in the Y direction.

Also, in the probe base plate 14, in the rows f, g and k, l, on both sides of the rows h, i and j, the arrangement regions α are formed on the second line corresponding to the line 2′ of the rows f, g and k, l on the semiconductor wafer 20, namely, in the regions on the most upstream side opposite to the moving direction of those rows. Thereafter, in the rows f, g and k, l on the probe base plate 14, the repetition pattern of one arrangement region α and two non-arrangement regions likewise continues in the Y direction.

Further, in the row e outside the rows f, g, and the rows d, c, b and a outside the row e, the arrangement regions α are formed respectively on the lines 3, 5, 6 8 and 11 which are regions located on the most upstream side opposite to the moving direction of those rows, and likewise, the repetition pattern of one arrangement region α and two non-arrangement regions continues in the Y-direction. Also, concerning the rows m, n, o, p and q outside the rows k, l, the arrangement regions α are formed respectively on the lines 3, 4, 5, 7 and 10 which are regions located on the most upstream side opposite to the moving direction of those rows, and likewise, the repetition pattern of one arrangement region α and two non-arrangement regions continue in the Y direction. In the row r, the single arrangement region α is formed on the line 16 only.

As a result, as apparent from FIG. 1, on each of lines except lines 1 and 31 of the rows h, i and j, the arrangement regions α of the probe 16 groups on the probe base plate 14 are formed discontinuously in the X direction and the Y direction.

In the inspection of the probe assembly 10, the probe assembly 10 is disposed on the semiconductor wafer 20 such that firstly the tips of the probe 16 groups on the first line of the rows h, i and j on the probe base plate 14 correspond to the respective connection pads of the IC chip regions on the line 1′ of in the rows h, i and j on the semiconductor wafer 20, while the tips of the probe 16 groups of the rows f, g and the rows k, l on both sides thereof correspond to the respective connection pads of the IC chip regions on the line 2′ of the rows f, g and the rows k, l on the semiconductor wafer 20, and the tips descend toward the semiconductor wafer 20. By this descent, each probe 16 group of the probe assembly 10 is connected to each of the connection pad of the IC chip region shown in FIG. 3 with diagonally left-up lines. Thereby, in the first inspection, an electrical inspection of the IC chip regions with diagonally left-up lines is conducted by using all the probe 16 groups on the probe assembly 10.

After the first inspection, the probe assembly 10 is separated upward from the semiconductor wafer 20 and, at the separated position, moved by the distance of one IC chip region in the Y direction. By this movement for the second inspection, for example, the tips of the probe 16 groups on the first line of the rows h, i and j on the probe base plate 14 correspond to the respective connection pads of the IC chip regions on the line 2′ of the rows h, i and j on the semiconductor wafer 20, and the tips of the probe 16 groups in the rows f, g and rows k, l on both sides thereof correspond to the respective connection pads of the IC chip regions on the line 3′ of the rows f, g and rows k, l on the semiconductor wafer 20.

For the second inspection, therefore, when the probe assembly 10 descends toward the semiconductor wafer 20, this descent connects each probe 16 group on the probe base plate 14 to each connection pad of the IC chip regions with diagonally right-up lines in FIG. 3. By this, in the second inspection, the probe 16 groups on the probe base plate 14 except those arranged on the row m, line 30, row c, line 27, row d, line 29 and row e, line 30 are used to perform an electrical inspection of the IC chip regions with diagonally right-up lines.

After the second inspection, the probe assembly 10 is separated upward from the semiconductor wafer 20 and moved further in the Y direction by the distance of one IC chip region for the third inspection. By this movement for the third inspection, the tips of the probe 16 groups on the first line of the rows h, i and j of the probe assembly 10 correspond to the respective connection pads of the IC chip regions on the line 3′ of the rows h, i and j of the semiconductor wafer 20, and the tips of the probe 16 groups in the rows f, g and rows k, l on both sides thereof correspond to the respective connection pads of the IC chip regions on the line 4′ of the rows f, g and rows k, l.

For the third inspection, therefore, when the probe assembly 10 descends toward the semiconductor wafer 20, each probe 16 group on the probe base plate 14 is connected by this descent with each connection pad of the IC chip regions with horizontal parallel lines in FIG. 3. Thereby, in the third inspection, the probe 16 groups other than those not used in the second inspection of the probe assembly 10 are used and, further, except those arranged in the rows h, i and j of the line 31, the row n of the line 28, the row p of the line 25, the row q of the line 22, and the row r of the line 16, to perform an electrical inspection of the IC chip regions with horizontal parallel lines.

As a result, in the first inspection, all the probes 16 are effectively used without resulting in non-use of any part of the probe 16 groups. Also, in the second and third inspections, not all the probe 16 groups are used but the majority of the probe 16 groups are effectively used. By these three inspections, efficient electrical inspection of all the IC chip regions on the semiconductor wafer 20 is realized, resulting in efficient inspection.

Further, by intending reduction in the number of not effectively used probe 16 groups, it is possible to reduce damages to abutting portions caused by unused probes 16 abutting on parts other than the connection pads of the IC chip regions, resulting in a longer longevity of the probes 16, thereby improving the durability of the probe assembly 10.

Also, since the probe 16 groups are not formed continuously on the probe base plate 14 in two directions, i.e., the X and Y directions, there is no need to arrange the probes 16 or their tips continuously with high density, so that the probe assembly 10 can be comparatively easily and inexpensively produced.

In the probe assembly 10 in FIG. 1 is shown an example that one tip arrangement region α having the probe 16 groups arranged and two non-arrangement regions are arranged in the Y direction repeatedly in the same pattern in each row. In place of this, it is possible to properly change the arrangement patterns of the arrangement regions α and the non-arrangement regions for arranging the probe 16 groups in arranging the probe assembly 10 on the probe base plate 14 in each line.

For example, in the arrangement of the probe 16 groups on the probe base plate 14, it is possible to make the arrangement mode in line in the X direction the same as the example shown in FIG. 1, while one arrangement region α and three non-arrangement regions can be repeated in the Y direction in each line.

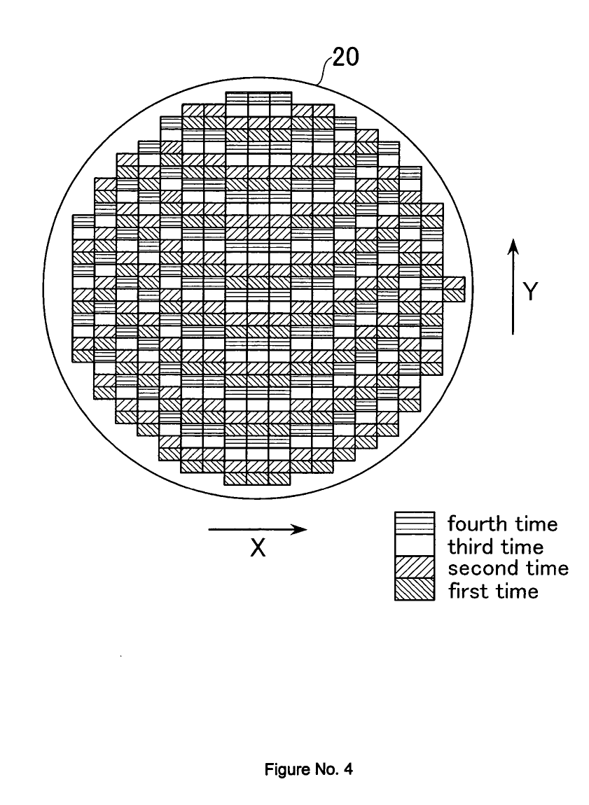

According to this arrangement, as shown in FIG. 4, the IC chip regions with diagonally left-up lines are tested in the first inspection, the IC chip regions with diagonally right-up lines are tested in the second inspection, the IC chip regions with void are tested in the third inspection, and the IC chip regions with horizontal parallel lines are tested in the last fourth inspection.

The arrangement regions α of the probe 16 groups on the probe base plate 14 in this case correspond to the IC chip regions with diagonally left-up lines to be tested in the first inspection. According to this example of arrangement, in comparison with the example shown in FIG. 1, the number of the non-used probe 16 groups increases somewhat and the number of inspections is increased by one, but since the number of the non-arrangement regions is increased, it is advantageous for easy production.

On the other hand, in the arrangement of the probe 16 groups on the probe base plate 14, it is possible to make the arrangement mode in line in the X direction the same as the example shown in FIG. 1, while one arrangement region α and one non-arrangement region are repeated in each row in the Y direction.

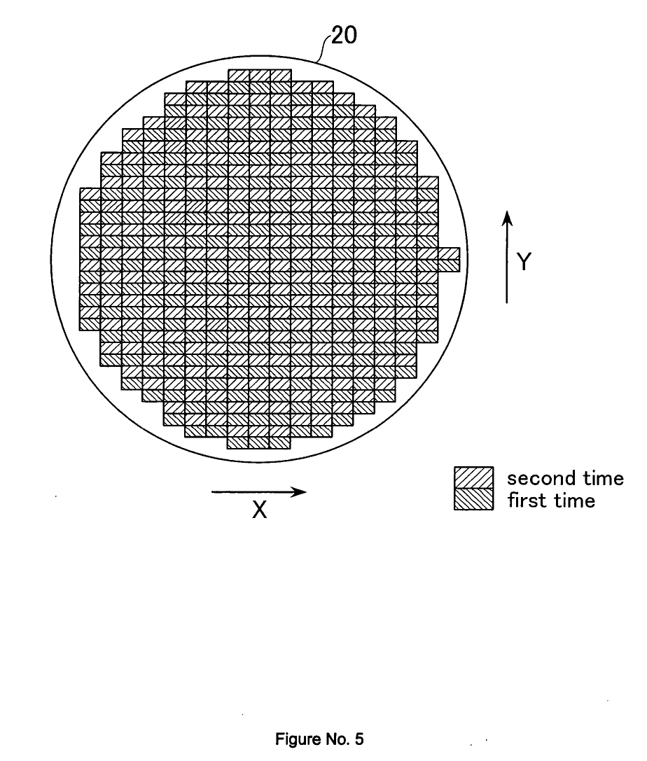

According to the probe assembly 10 using this example of arrangement, as shown in FIG. 5, the IC chip regions with diagonally left-up lines are tested in the first inspection, and the IC chip regions with diagonally right-up lines are tested in the second inspection, and with these two inspections, the electrical inspection of all the IC chip regions on the semiconductor wafer 20 is finished. In addition, the arrangement regions α of the tips of the probe 16 groups on the probe base plate 14 correspond to the IC chip regions with diagonally left-up lines to be tested in the first inspection and correspond to the IC chip regions with diagonally right-up lines to be tested in the second inspection, so that all the probes 16 can be effectively used in both inspections without resulting in non-use of part of the probe 16 groups.

Therefore, there is no causing any damage due to abutting of part of unused probes 16 on parts other than the connection pads, thereby extending the longevity of the probes 16 and improving the durability of the probe assembly 10.

By the arrangement of the probes 16 of the probe base plate 14 according to the present invention, the number of rows in the X direction on the probe base plate 14 coincides with that of the chip regions on the semiconductor wafer 20.

In any of the foregoing examples, in each row on the probe base plate 14, the probe arrangement regions α is not continuous in the Y direction, but a plurality of probe arrangement regions α can be continuously arranged between the non-arrangement regions, if necessary. In this case, suppose that the number of the continuous probe arrangement regions α in each row is N (in the foregoing example, since the probe arrangement regions α are not continuous in the Y direction, the value of N is “1” in any case), that the number of the continuous non-arrangement regions is M, and that the number of the chip regions in the corresponding rows on the semiconductor wafer 20 is W, the number of the continuous regions formed by the N arrangement regions α existing in the corresponding row can be determined on the basis of the quotient when W is divided by the sum of N plus M. That is to say, the number of the continuous regions having the N arrangement regions α is determined basically such that, when W/(N+M) is divisible, there are W/(N+M) rows, each row having N arrangement regions α, while when there is a remainder, there are as much as the quotient of W/(N+M) plus 1 rows, each row having N arrangement regions α.

### INDUSTRIAL APPLICABILITY

The present invention is not limited to the above-mentioned embodiments but can be variously modified without departing from its purport. For example, in correspondence to the symmetrical arrangement of the IC chip regions on the semiconductor wafer 20, the arrangement region α of the probe 16 groups and the non-arrangement regions can be arranged relative to the diameter in the Y direction of the probe base plate 14. Also, the number in series in the X direction of the arrangement region α in each line can be properly selected.

What is claimed:

1. A probe assembly comprising a probe base plate for use in electrical inspection of a plurality of semiconductor chip regions formed continuously in alignment in directions orthogonal to each other on a substantially circular semiconductor wafer, and with a plurality of probes capable of contacting an electrical connecting portions of each semiconductor chip region, wherein said probe base plate has a dimension large enough to cover said semiconductor wafer, wherein tips of a plurality of probe groups are arranged in the X and Y directions orthogonal to each other of one of the faces of said probe base plate in correspondence to predetermined rectangular chip region groups including the predetermined number of the semiconductor chip regions, wherein arrangement regions of the tips of said probe groups are formed discontinuously in both of the X and Y directions, thereby enabling the electrical inspection of all the chip region groups in either of the X and Y directions by relative feeding movement with said semiconductor wafer in either one of the X and Y directions.

2. A probe assembly claimed in claim 1, wherein, when the electrical inspection is repeated with movement in the Y direction, the arrangement regions of the tips of the probe groups are respectively formed in the regions of the probe base plate corresponding to the rectangular chip regions located on the most upstream side opposite to the moving direction in each line of said semiconductor wafer along the Y direction, and wherein on said probe base plate the predetermined number of the tip arrangement regions and the non-arrangement regions with no tips are formed by repeating the same pattern in the moving direction.

3. A probe assembly claimed in claim 2, wherein said arrangement region of the tips corresponding to one rectangular chip region group and said non-arrangement regions of the tips corresponding to two rectangular chip region groups are arrayed alternately in each line in the Y direction.

4. A probe assembly claimed in claim 2, wherein said tip arrangement region corresponding to one rectangular chip region group and said non-arrangement regions with no tips corresponding to three of said rectangular chip region groups in each line are alternately arrayed in the Y direction.

5. A probe assembly claimed in claim 2, wherein the pattern of the tip arrangement regions and the non-arrangement regions without tips of said probe groups are asymmetrical with respect to the center line along the Y direction.
